(19) United States
(12) Patent Application Publication
(10) Pub. No.: US 2019/0127842 A1
(43) Pub. Date: May 2, 2019

(54) PULSED DC SOURCE FOR HIGH POWER IMPULSE MAGNETRON SPUTTERING PHYSICAL VAPOR DEPOSITION OF DIELECTRIC FILMS AND METHODS OF APPLICATION

(71) Applicant: APPLIED MATERIALS, INC., Santa Clara, CA (US)

(72) Inventors: Viachslav BABAYAN, Sunnyvale, CA (US); Adolph Miller ALLEN, Oakland, CA (US); Bhargav CITLA, Fremont, CA (US); Ronald D. DEDORE, Scotts Valley, CA (US); Vanessa FAUNE, San Jose, CA (US); Zhong Qiang HUA, Saratoga, CA (US); Vaibhav SONI, Sunnyvale, CA (US); Menglu WU, Alviso, CA (US)

(21) Appl. No.: 15/797,361

(22) Filed: Oct. 30, 2017

(51) Int. Cl. C23C 14/34; C23C 14/06; C23C 14/35; H01J 37/34; H01L 21/02

(52) U.S. Cl. CPC C23C 14/3485; C23C 14/0605; C23C 14/35; H01L 21/02115; H01J 37/3467; H01J 37/3426; H01L 21/02266; H01J 37/3405

(57) ABSTRACT

An apparatus and method of forming a dielectric film layer using a physical vapor deposition process include delivering a sputter gas to a substrate positioned in a processing region of a process chamber, the process chamber having a dielectric-containing sputter target, delivering an energy pulse to the sputter gas to create a sputtering plasma, the sputtering plasma being formed by energy pulses having an average voltage between about 800 volts and about 2000 volts and an average current between about 50 amps and about 300 amps at a frequency which is less than 50 kHz and greater than 5 kHz and directing the sputtering plasma toward the dielectric-containing sputter target to form an ionized species comprising dielectric material sputtered from the dielectric-containing sputter target, the ionized species forming a dielectric-containing film on the substrate.

### FIELD

Embodiments of the present principles generally relate to a method and apparatus for deposition of a film and a more specifically to a pulsed high power impulse magnetron sputtering (HIPIMS) source for deposition of dielectric HiPIMS physical vapor deposition (PVD) films and method thereof.

### BACKGROUND

As the semiconductor industry introduces new generations of integrated circuits (IC's) having higher performance and greater functionality, the density of the elements that form those IC's is increased, while the dimensions, size and spacing between the individual components or elements are reduced. While in the past such reductions were limited only by the ability to define the structures using photolithography, device geometries having dimensions measured in micrometers or nanometers have created new limiting factors, such as the conductivity of the conductive interconnects, the dielectric constant of the insulating material(s) used between the interconnects, etching the small structures or other challenges in 3D NAND or DRAM form processes. These limitations may be benefited by more durable, higher density and higher hardness hardmasks.

A thick dielectric hardmask, such as a carbon hardmask, is well known and commonly used as POR film. However, current dielectric hardmasks such as graphitic, Sp2 type, or other carbon hardmask compositions are expected to be insufficient as DRAM and NAND continue their scaling down to under about 10 nm regime. Such downscaling will require even higher aspect ratio deep contact hole or trench etch. The high aspect ratio etch issues include clogging, hole-shape distortion, and pattern deformation, top critical dimension blow up, line bending, profile bowing are generally observed in these applications. Many etch challenges are dependent on the hardmask material property. Deep contact hole deformation can be related to lower hardmask density and high particle count. Slit pattern deformation or line bending is due to hardmask material lower selectivity and stress. Therefore, the inventors believe that an etch hardmask with higher density, higher etch selectivity, lower stress, and higher reflectivity index would be desirable.

### SUMMARY

Embodiments of apparatus and methods of forming a dielectric film layer using a physical vapor deposition process are provided herein.

In some embodiments, a method of forming a dielectric film layer using a physical vapor deposition process includes delivering a sputter gas to a substrate positioned in a processing region of a process chamber, the process chamber having a dielectric-containing sputter target, delivering an energy pulse to the sputter gas to create a sputtering plasma, the sputtering plasma being formed by energy pulses having an average voltage between about 800 volts and about 2000 volts and an average current between about 50 amps and about 300 amps at a frequency which is less than 50 kHz and greater than 5 kHz and directing the sputtering plasma toward the dielectric-containing sputter target to form an ionized species comprising dielectric material sputtered from the dielectric-containing sputter target, the ionized species forming a dielectric-containing film on the substrate.

In some embodiments an apparatus for providing energy pulses for forming a dielectric film layer using a physical vapor deposition process includes a power supply to provide power, a charging circuit to accumulate power to provide high power, and a discharge circuit to provide energy pulses. In at least one embodiment, the apparatus is configured to provide energy pulses to a sputter gas proximate a substrate positioned in a processing region of a process chamber, the process chamber having a dielectric-containing sputter target to create a sputtering plasma, the energy pulses having an average voltage between about 800 volts and about 2000 volts and an average current between about 50 amps and about 300 amps at a frequency which is less than 50 kHz and greater than 5 kHz.

In some embodiments a method of forming a carbon film layer using a physical vapor deposition process includes delivering a sputter gas to a substrate positioned in a processing region of a process chamber, the process chamber having a carbon-containing sputter target, delivering an energy pulse to the sputter gas to create a sputtering plasma, the sputtering plasma being formed by energy pulses having an average voltage between about 800 volts and about 2000 volts and an average current between about 50 amps and about 300 amps at a frequency which is less than 50 kHz and greater than 5 kHz, and forming an ionized species comprising a carbon material sputtered from the carbon-containing sputter target, wherein the ionized species forms a carbon-containing film layer on the substrate.

Other and further embodiments of the present principles are described below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the present principles and are therefore not to be considered limiting of scope, for the present principles may admit to other equally effective embodiments.

FIG. 1 depicts a schematic cross-sectional view of a physical vapor deposition (PVD) process chamber in accordance with embodiments of the present principles.

FIG. 2 depicts a high level schematic diagram of a hybrid high power impulse magnetron sputtering (HIPIMS) power source in accordance with an embodiment of the present principles.

FIG. 3 depicts a graph of particle count as a function of an increase in frequency resultant from a HIPIMS PVD process in accordance with an embodiment of the present principles.

FIG. 4 depicts a pictorial view of the morphology of a carbon film produced using two different frequencies in accordance with the present principles.

FIG. 5 depicts a flow diagram of a method for forming a dielectric film layer using a PVD process in accordance with an embodiment of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

In the following detailed description, numerous specific details are set forth in order to provide a thorough understanding of exemplary embodiments or other examples described herein. However, these embodiments and examples may be practiced without the specific details. In other instances, well-known methods, procedures, components, and/or circuits have not been described in detail, so as not to obscure the following description. Further, the embodiments disclosed are for exemplary purposes only and other embodiments may be employed in lieu of, or in combination with, the embodiments disclosed.

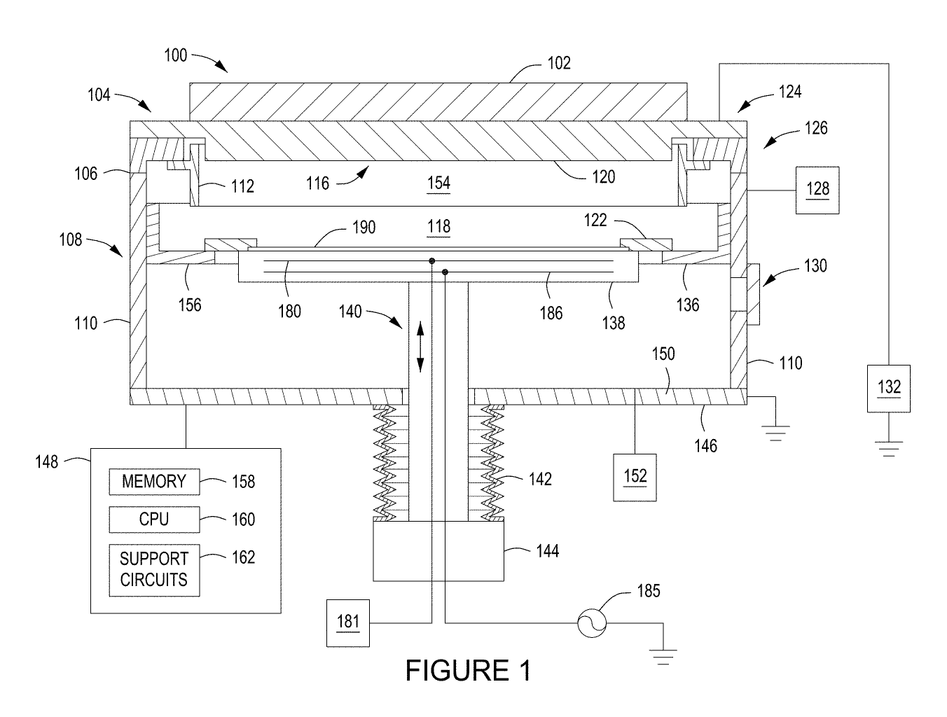

FIG. 1 illustrates an exemplary physical vapor deposition (PVD) process chamber 100 (e.g., a sputter process chamber) suitable for sputter depositing materials using a high power impulse magnetron sputtering (HIPIMS) process in accordance with an embodiment of the present principles. One example of the process chamber that may be adapted to form the dielectric film in accordance with the present principles is a PVD process chamber, available from Applied Materials, Inc., located in Santa Clara, Calif. Other sputter process chambers, including those from other manufactures, may be adapted to practice the present principles.

The process chamber 100 includes a chamber body 108 having a processing volume 118 defined therein. The chamber body 108 has sidewalls 110 and a bottom 146. The dimensions of the chamber body 108 and related components of the process chamber 100 are not limited and generally are proportionally larger than the size of the substrate 190 to be processed. Any suitable substrate size may be processed. Examples of suitable substrate sizes include substrate with 200 mm diameter, 300 mm diameter, 450 mm diameter or larger.

A chamber lid assembly 104 is mounted on the top of the chamber body 108. The chamber body 108 may be fabricated from aluminum or other suitable materials. A substrate access port 130 is formed through the sidewall 110 of the chamber body 108, facilitating the transfer of a substrate 190 into and out of the process chamber 100. The access port 130 may be coupled to a transfer chamber and/or other chambers of a substrate processing system.

A gas source 128 is coupled to the chamber body 108 to supply process gases into the processing volume 118. In one embodiment, process gases may include inert gases, non-reactive gases, and reactive gases if necessary. Examples of process gases that may be provided by the gas source 128 include, but not limited to, argon gas (Ar), helium (He), neon gas (Ne), krypton (Kr), xenon (Xe), nitrogen gas (N.sub.2), oxygen gas (O.sub.2), hydrogen gas (H.sub.2), forming gas (N.sub.2+H.sub.2), ammonia (NH.sub.3), methane (CH.sub.4), carbon monoxide (CO), and/or carbon dioxide (CO.sub.2), among others.

A pumping port 150 is formed through the bottom 146 of the chamber body 108. A pumping device 152 is coupled to the processing volume 118 to evacuate and control the pressure therein. A pumping system and chamber cooling design enables high base vacuum (e.g., 1 E-8 Torr or less) and low rate-of-rise (e.g., 1,000 mTorr/min) at temperatures (e.g., −25 degrees Celsius to +650 degrees Celsius) suited to thermal budget needs. The pumping system is designed to provide precise control of process pressure which is a critical parameter for crystal structure (e.g., Sp3 content), stress control and tuning. Process pressure may be maintained in the range of between about 1 mTorr and about 500 mTorr, such as between about 2 mTorr and about 20 mTorr.

The lid assembly 104 generally includes a target 120 and a ground shield assembly 126 coupled thereto. The target 120 provides a material source that can be sputtered and deposited onto the surface of the substrate 190 during a PVD process. Target 120 serves as the cathode of the plasma circuit during, for example, DC sputtering.

The target 120 or target plate may be fabricated from a material utilized for the deposition layer, or elements of the deposition layer to be formed in the chamber such as dielectric materials. A high voltage power supply, such as a power source 132, is connected to the target 120 to facilitate sputtering materials from the target 120. In one embodiment, the target 120 may be fabricated from carbon or a carbon containing material, such as a material including graphite, amorphous carbon, combinations thereof, or the like. The target could also be graphitic and/or contain Sp2 type carbon material structures. The deposition process may benefit from the use of an Sp2 material containing deposition target for the deposition of an Sp3 layer, as Sp2 carbon materials are structurally closer to Sp3, than other less structured carbon targets. In one embodiment, the target is a graphitic target. The power source 132, or power supply, can provide power to the target in a pulsed (as opposed to constant) manner. That is, power supply can provide power to target by providing a number of pulses to target.

The target 120 generally includes a peripheral portion 124 and a central portion 116. The peripheral portion 124 is disposed over the sidewalls 110 of the chamber. The central portion 116 of the target 120 may have a curvature surface slightly extending towards the surface of the substrate 190 disposed on a substrate support 138. In some embodiments, the spacing between the target 120 and the substrate support 138 is maintained between about 50 mm and about 250 mm. The dimension, shape, materials, configuration, and diameter of the target 120 may be varied for specific process or substrate requirements. In one embodiment, the target 120 may further include a backing plate having a central portion bonded and/or fabricated by a material desired to be sputtered onto the substrate surface.

The lid assembly 104 may further comprise a full face erosion magnetron cathode 102 mounted above the target 120 which enhances efficient sputtering materials from the target 120 during processing. The full face erosion magnetron cathode 102 allows easy and fast process control and tailored film properties while ensuring consistent target erosion and uniform deposition across the wafer. Examples of a magnetron assembly include a linear magnetron, a serpentine magnetron, a spiral magnetron, a double-digitated magnetron, a rectangularized spiral magnetron, among others shapes to form a desired erosion pattern on the target face and enable a desirable sheath formation during pulsed or DC plasma stages of the process. In some configurations, the magnetron may include permanent magnets that are positioned in a desirable pattern over a surface of the target, such as one of the patterns described above (e.g., linear, serpentine, spiral, double digitated, etc.). In other configurations, a variable magnetic field type magnetron having a desirable pattern may alternately, or even in addition to permanent magnets, be used to adjust the shape and/or density of the plasma throughout one or more portions of a HIPMS process.

The ground shield assembly 126 of the lid assembly 104 includes a ground frame 106 and a ground shield 112. The ground shield assembly 126 may also include other chamber shield member, target shield member, dark space shield, and dark space shield frame. The ground shield 112 is coupled to the peripheral portion 124 by the ground frame 106 defining an upper processing region 154 below the central portion of the target 120 in the processing volume 118. The ground frame 106 electrically insulates the ground shield 112 from the target 120 while providing a ground path to the chamber body 108 of the process chamber 100 through the sidewalls 110. The ground shield 112 constrains plasma generated during processing within the upper processing region 154 and dislodges target source material from the confined central portion 116 of the target 120, thereby allowing the dislodged target source material to be mainly deposited on the substrate surface rather than chamber sidewalls 110.

A shaft 140 extending through the bottom 146 of the chamber body 108 couples to a lift mechanism 144. The lift mechanism 144 is configured to move the substrate support 138 between a lower transfer position and an upper processing position. A bellows 142 circumscribes the shaft 140 and coupled to the substrate support 138 to provide a flexible seal there between, thereby maintaining vacuum integrity of the chamber processing volume 118.

The substrate support 138 may be an electro-static chuck and have an electrode 180. The substrate support 138, when using the electro-static chuck (ESC) embodiment, uses the attraction of opposite charges to hold both insulating and conducting type substrates 190 and is powered by DC power supply 181. The substrate support 138 can include an electrode embedded within a dielectric body. The DC power supply 181 may provide a DC chucking voltage of about 200 to about 2000 volts to the electrode. The DC power supply 181 may also include a system controller for controlling the operation of the electrode 180 by directing a DC current to the electrode for chucking and de-chucking the substrate 190.

The temperature of the PVD process may be kept below the temperature at which the deposited film properties may become undesirable. For example, temperature may be less than about 250 degrees Celsius and have about a 50 degrees Celsius margin to assist in depositing a dielectric layer. The substrate support 138 performs in the temperature range required by the thermal budget of the device integration requirements. For example, the substrate support 138 may be a detachable electrostatic chuck (ESC) for minus 25 degrees Celsius to 100 degrees Celsius temperature range, mid-temp ESC for 100 degrees Celsius to 200 degrees Celsius temperature range, high temperature or high temperature biasable or high temperature high uniformity ESC for temperatures ranging from 200 degrees Celsius to 500 degrees Celsius which ensures fast and uniform heating up of wafers.

After the process gas is introduced into the process chamber 100, the gas is energized to form plasma so that the HIPIMS type PVD process can be performed. An example of a HIPIMS type PVD process is described further below.

A shadow frame 122 is disposed on the periphery region of the substrate support 138 and is configured to confine deposition of source material sputtered from the target 120 to a desired portion of the substrate surface. A chamber shield 136 may be disposed on the inner wall of the chamber body 108 and have a lip 156 extending inward to the processing volume 118 configured to support the shadow frame 122 disposed around the substrate support 138. As the substrate support 138 is raised to the upper position for processing, an outer edge of the substrate 190 disposed on the substrate support 138 is engaged by the shadow frame 122 and the shadow frame 122 is lifted up and spaced away from the chamber shield 136. When the substrate support 138 is lowered to the transfer position adjacent to the substrate transfer access port 130, the shadow frame 122 is set back on the chamber shield 136. Lift pins (not shown) are selectively moved through the substrate support 138 to list the substrate 190 above the substrate support 138 to facilitate access to the substrate 190 by a transfer robot or other suitable transfer mechanism.

A controller 148 is coupled to the process chamber 100. The controller 148 includes a central processing unit (CPU) 160, a memory 158, and support circuits 162. The controller 148 is utilized to control the process sequence, regulating the gas flows from the gas source 128 into the process chamber 100 and controlling ion bombardment of the target 120. The CPU 160 may be of any form of a general purpose computer processor that can be used in an industrial setting. The software routines can be stored in the memory 158, such as random access memory, read only memory, floppy or hard disk drive, or other form of digital storage. The support circuits 162 are conventionally coupled to the CPU 160 and may comprise cache, clock circuits, input/output subsystems, power supplies, and the like. The software routines, when executed by the CPU 160, transform the CPU into a specific purpose computer (controller) 148 that controls the process chamber 100, such that the processes are performed in accordance with the present principles. The software routines may also be stored and/or executed by a second controller (not shown) that is located remotely from the process chamber 100.

During processing, material is sputtered from the target 120 and deposited on the surface of the substrate 190. In some configurations, the target 120 is biased relative to ground or substrate support, by the power source 132 to generate and maintain a plasma formed from the process gases supplied by the gas source 128. The ions generated in the plasma are accelerated toward and strike the target 120, causing target material to be dislodged from the target 120. The dislodged target material forms a layer on the substrate 190 with a desired crystal structure and/or composition. RF, DC or fast switching pulsed DC power supplies or combinations thereof provide tunable target bias for precise control of sputtering composition and deposition rates for the dielectric material.

In some embodiments, separately applying a bias to the substrate during different phases of the dielectric layer deposition process is also desirable. Therefore, a bias may be provided to a bias electrode 186 (or chuck electrode 180) in the substrate support 138 from a source 185 (e.g., DC and/or RF source), so that the substrate 190 will be bombarded with ions formed in the plasma during one or more phases of the deposition process. In some process examples, the bias is applied to the substrate after the dielectric film deposition process has been performed. Alternately, in some process examples, the bias is applied during the dielectric film deposition process. A larger negative substrate bias will tend to drive the positive ions generated in the plasma towards the substrate or vice versa, so that they have a larger amount of energy when they strike the substrate surface.

Referring back to the embodiment of FIG. 1, the power source 132 of the embodiment of FIG. 1 is a hybrid HIPIMS power source developed by the inventors. The hybrid HIPIMS power source 132 in accordance with the present principles is configured to deliver power impulses with high current, such as between about 50 amps and about 300 amps, and voltage ranges from about 800V to about 2000V over short durations, between about 5 μs and about 100 μs at a frequency of between about 5 kHz and about 50 kHz. That is, the inventors have determined that to produce high density, dielectric films with desired uniformity and amorphous properties, a signal having high voltage, high frequency, shorter time duration power pulses in the ranges described above can be provided by a respective power source in accordance with embodiments of the present principles.

In contrast to the hybrid HIPIMS power source of the present principles, conventional HiPIMS generators operate in a frequency range of between 50 Hz and 5 kHz and typically output 4000 A and voltages over 2000V. Providing high voltage pulses at such low frequencies has been determined by the inventors to be inadequate for achieving roughness/morphology requirements of dielectric material films, such as carbon films, produced using a PVD process. That is, providing high voltage pulses at low frequencies results in arcs and causes high particle counts in dielectric material films produced using a PVD process.

In further contrast to the hybrid HIPIMS power source of the present principles, conventional pulsed DC generators that are used with PVD chambers operate in a frequency range of between 50 kHz and 300 kHz and produce 40 A of current and 800V. The frequency ranges provided by conventional pulsed DC generators have been determined by the inventors to be too fast to reach appropriate deposition rates for dielectric material films produced using a PVD process. In addition, the inventors have determined that the power provided by conventional pulsed DC generators is not high enough to produce high density plasma that is needed for processing dielectric materials such as carbon.

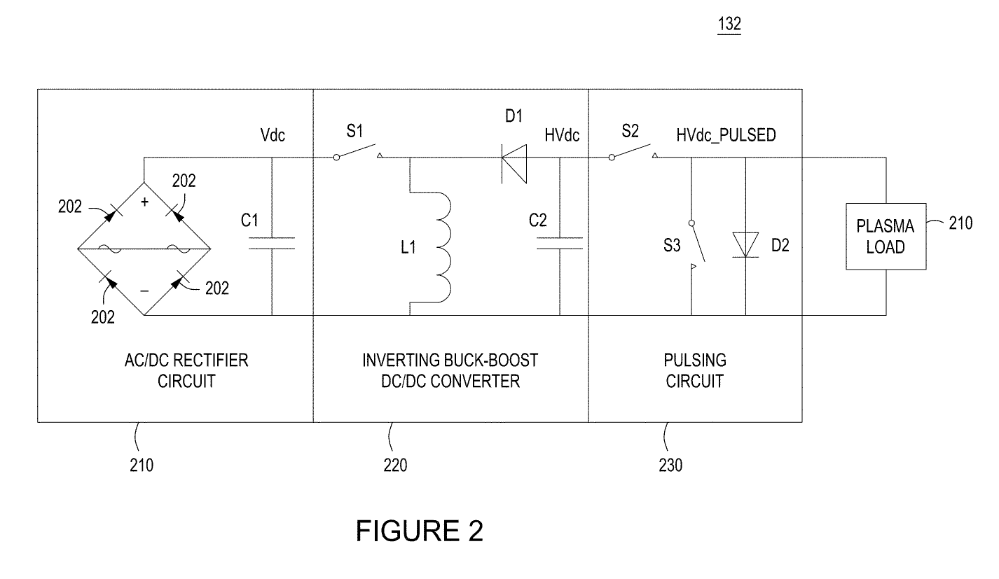

FIG. 2 depicts a high level schematic diagram of a hybrid HIPIMS power source 132 in accordance with an embodiment of the present principles. The hybrid HIPMS of the embodiment of FIG. 2 illustratively comprises an AC/DC rectifier circuit 210, a Buck-Boost circuit 220 and a Pulsing circuit 230.

Illustratively, in the AC/DC rectifier circuit 210, rectifier diodes, collectively diodes 202, convert AC to DC and charge a capacitor, C1, to a Vdc level. The Buck-Boost circuit converts Vdc to a negative HV dc signal by adjusting the duty cycle of the switch, S1. That is, when the switch, S1 is closed, Vdc charges the inductor, L1 and diode, D1, blocks current from flowing into capacitor, C2. When S1 is open, inductor, L1, charges capacitor, C2, creating negative voltage (HVdc). In the hybrid HIPIMS power source 132 of FIG. 2, the duty Cycle of switch, S1, defines the magnitude of HVdc with respect to Vdc.

The Pulsing Circuit 230 of FIG. 2 generates an HV Pulsed DC signal. In the Pulsing Circuit 230, when switch, S2, is closed and switch, S3, is open, HVdc is applied to the load, illustratively plasma. When switch, S2, is open and switch, S3, is closed, the load is grounded. Diode, D2, ensures that load voltage doesn't becomes positive when switch, S3, grounds the load.

In accordance with the present principles, the hybrid HIPIMS power source 132 of FIG. 2 is configured to deliver power impulses with high current, such as between about 50 A and about 300 A, high power, such as between about 5 kW and about 40 kW and voltage ranges from 800V to about 2000V over short durations, between about 5 μs and about 100 μs at a frequency of between about 5 kHz and 50 kHz.

In one experiment, a chamber pressure was set at 8 mT and the HV Pulsed DC signal provided by a hybrid HIPIMS power source of the present principles, such as the HIPIMS power source 132 of FIGS. 1 and 2, was set to 1500V. In the experiment, the HV Pulsed DC signal was provided at a frequency of approximately 40 kHz. At such a frequency, an on-time duration of approximately only 5 μs was needed to ignite the plasma. At a frequency of approximately 40 kHz and an on-time duration of approximately 5 μs, the current reached approximately 80 amps.

In contrast, in another experiment, a similar chamber pressure was set at 8 mT and an HV Pulsed DC signal was again provided at 1500V, however the HV Pulsed DC signal was provided at a frequency of just under 5 kHz. At such a frequency, an on-time duration of approximately 25 μs was needed to ignite the plasma. At a frequency of just under 5 kHz and an on-time duration of approximately 25 μs, the current reached approximately 150 amps.

As illustrated by the experimental examples described above, by providing an HV Pulsed DC signal at higher frequencies than available with conventional HIPIMS power sources, a hybrid HIPIMS power source in accordance with the present principles is able to ignite plasma using shorter on-times which results in lower peak currents. The lower peak currents result in lower particle counts in produced dielectric films due to, for example, less arcing and result in dielectric films having reduced deposition rates, improved refractive index (RI) and morphology.

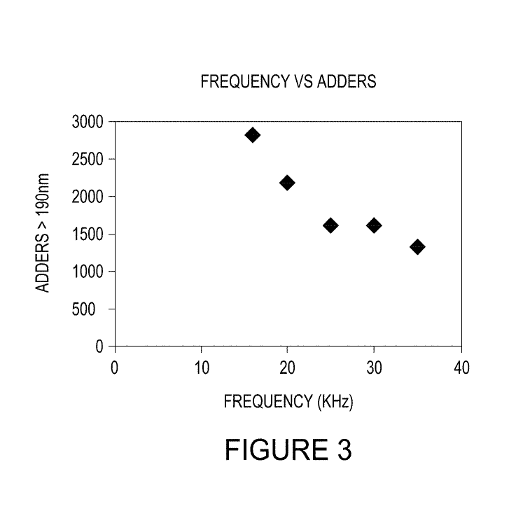

For example, FIG. 3 depicts a graph of particle count as a function of an increase in frequency resultant from a high power impulse magnetron sputtering (HIPIMS) PVD process in accordance with an embodiment of the present principles. As depicted in FIG. 3, as the frequency of a HV Pulsed DC signal from a hybrid HIPIMS power source in accordance with the present principles, having the power ranges and on-time ranges described above, increases from illustratively 16 kHz to 35 kHz, the particle count (e.g. adders) of a dielectric film layer, for example a 6000 angstrom carbon film, decreases significantly. That is, as can be seen in the embodiment of FIG. 3, when an HV Pulsed DC signal from a hybrid HIPIMS source in accordance with the present principles is delivered at a frequency of 16 kHz, 2821 adders are detected in a produced carbon film layer. As further depicted in FIG. 3, at a frequency of 20 kHz, 2184 adders are detected; at a frequency of 25 kHz, 1615 adders are detected; at a frequency of 30 kHz, 1602 adders are detected; and at a frequency of 35 kHz, only 1324 adders were detected in a carbon film layer produced on a substrate resulting from a high power impulse magnetron sputtering (HIPIMS) PVD process in accordance with an embodiment of the present principles. Generally, as depicted in FIG. 3, keeping process conditions the same and for a fixed duty cycle, as frequency is increased, particle count decreases. The inventors further noted that as frequency is increased, deposition rate decreases and RI (or density) remains mostly constant.

As previously described above, one explanation for the improvement in particle count when higher frequencies are used in accordance with the present principles is that shorter on-time pulses with lower peak current result in reduced arcs/micro-arcs on the surface of the target which result in higher particle counts in the dielectric films produced. In addition, another explanation can be that shorter on-time pulses with lower peak current also minimize surface heating of a target which can result in mechanical deflection of particles from the target due to thermal stress.

It should be noted though that as pulse duration decreases due to, for example an increase in frequency, peak current reduces almost linearly. As such a total power delivered by an HV Pulsed DC signal from a hybrid HIPIMS source in accordance with the present principles is lowered. To compensate for this effect a voltage provided can be increased while increasing frequency and providing shorter on-time pulses. That is, a voltage/total power provided by a power source still needs to be high enough to ignite plasma and to produce high density plasma that is needed for processing dielectric materials at the higher frequency and shorter pulse times in accordance with the present principles and achieve desired dep rates and meet roughness/morphology requirements of dielectric material films.

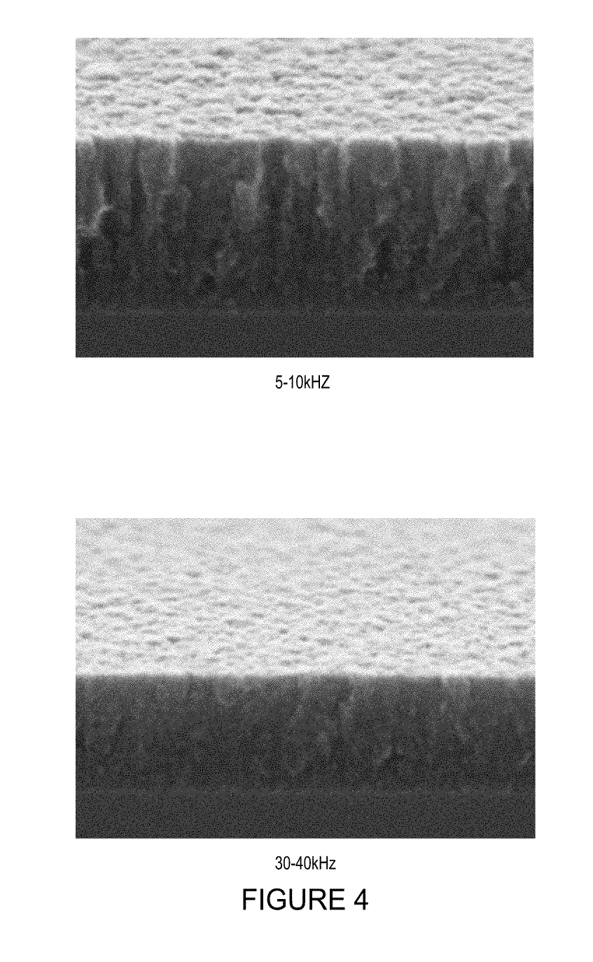

FIG. 4 depicts a pictorial view of the morphology of a carbon film produced using two different frequencies in accordance with the present principles. Specifically, FIG. 4 depicts a comparison of the morphology of a 6000 angstrom film of carbon produced using a frequency between 5-10 kHz and a frequency between 30-40 kHz. As depicted in FIG. 4, at the higher frequency of between 30-40 kHz, the deposition of the carbon film is much more amorphous. That is, the inventors have determined that, using pulses in the power ranges described herein in accordance with the present principles, along with higher frequencies, in the ranges described herein in accordance with the present principles, improve the morphology of the deposition of dielectrics, such as carbon, as the deposition rate slightly decreases. More specifically, due at least partly to the higher frequencies and shorter on-time pulses for an HV Pulsed DC signal in the ranges described above used for a PVD process in accordance with the present principles, the current rise of a pulse is limited, which leads to a decrease in deposition rates and a decrease in particle deposition, which improves morphology and decreases surface roughness. Although, at higher frequencies the stress of a dielectric film may increase slightly, the increases in stress at higher frequencies, in the ranges as described above, are considered negligible in comparison to the benefits of using higher frequencies and specifically the reduced particle count and improved film morphology and roughness.

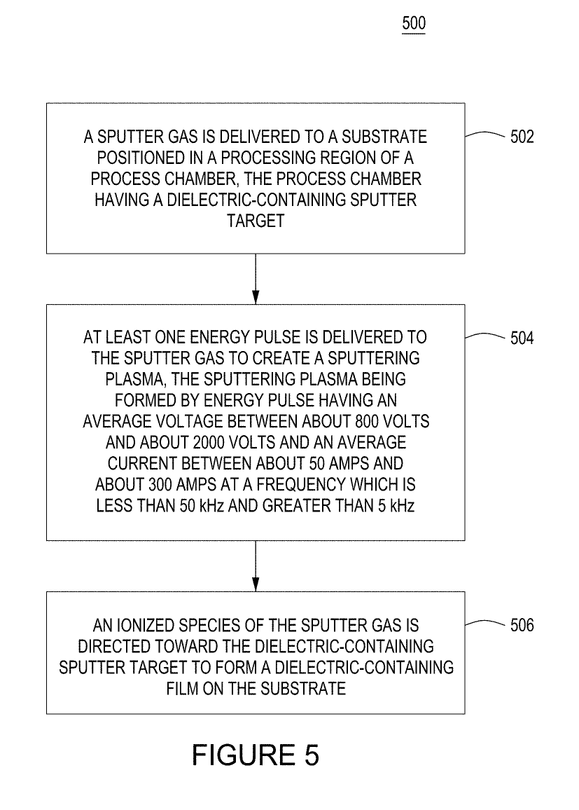

FIG. 5 depicts a flow diagram of a method 500 for forming a dielectric film layer using a physical vapor deposition process in accordance with an embodiment of the present principles. The method 500 can begin at 502 during which a sputter gas is delivered to, for example, a processing volume of a process chamber having a substrate as described above with respect to FIG. 1. In some embodiments, the process chamber has a dielectric-containing target, such as a carbon target. The sputter gas can be a gas which is inert to the substrate or the sputter target. In one embodiment, the sputter gas can be argon. The method 500 can then proceed to 504.

At 504, at least one energy pulse, and typically a series of energy pulses, are delivered to the sputter gas to create a sputtering plasma. In general, the energy pulses provided during 504 include the selection of at least a target bias voltage, pulse width and pulse frequency that form a plasma that will impart a desirable amount of energy to achieve a desirable plasma energy and plasma density to achieve a high ionization rate and degree of ionization to the sputtered atoms to achieve a desirable HIPIMS sputter deposition rate, film crystal structure and film density. In one embodiment and as described above, the energy pulses used to form the sputtering plasma can each have an average voltage between about 800 volts and about 2000 volts, an average current between about 50 amps and about 300 amps, a pulse width which is less than 100 microseconds and greater than 5 microseconds at a frequency which is less than 50 kHz and greater than 5 kHz. The method 500 can then proceed to 506.

At 506, once the plasma is formed, an ionized species of the sputter gas (sputtering plasma) is accelerated (directed) towards the dielectric-containing target material and collides with it. These collisions remove target atoms forming an ionized species comprising a dielectric material sputtered from the dielectric-containing target. The target atoms deposit on the surface of the substrate and form a solid, dielectric-containing film on the substrate. The method 500 can then be exited. In an alternate embodiment with respect to the dielectric material comprising carbon, 506 can include delivering the sputtering plasma to the sputter target to form an ionized species comprising carbon sputtered from the carbon-containing sputter target, wherein the ionized species forms a carbon-containing film layer on the substrate.

The energy pulse power, the frequency and the pulse duration, as described above and in accordance with the present principles, allow for a dielectric film layer having increased density and amorphous properties with reduced particle count to be formed on a substrate.

As stated above, a hybrid HIPIMS power source in accordance with the present principles can deliver power impulses at higher voltages than conventional pulsed DC generators over short durations at higher frequencies than conventional HIPIMS generators to generate amorphous, high density, dielectric films during an HIPIMS PVD process. More specifically, a hybrid HIPIMS power source in accordance with the present principles is capable of providing high current, such as between about 50 A and about 300 A, high voltage, such as between about 800V and about 2000V over short durations, between about 5 μs and about 100 μs having a frequency of between about 5 KHz and 50 KHz.

The power or energy delivered over the pulse cycle time may have a non-square wave shape during an on-time duration, and thus the average power over the time duration is reduced as compared to similar pulses delivered at lower frequencies. In some embodiments, each power impulse provided to the target can have equal amounts of power and/or equal durations. However, embodiments of the present disclosure are not so limited. For example, each pulse provided to the target can have a different amount of power and/or a different duration. The values quoted are to be understood purely as by way of example and can be varied in wide limits. The time in which a high power is applied to the target (cathode) is often limited by the rating of the power supply and the recharge time for the power supply to recharge during an intervening period.

As described above, an increase in pulse frequency as compared to a typical HIPIMS source to the ranges described herein and in increase in a pulse voltage as compared to a typical DC pulsed generator to the ranges described herein in accordance with embodiments of the present principles, reduces, deposition rate, particle defects and surface roughness and improves morphology in a dielectric film produced using an HIPIMS PVD process in accordance with the present principles.

While the foregoing is directed to embodiments of the present principles, other and further embodiments may be devised without departing from the basic scope thereof.

1. A method of forming a dielectric film layer using a physical vapor deposition process, comprising:
delivering a sputter gas to a substrate positioned in a processing region of a process chamber, the process chamber having a dielectric-containing sputter target;
delivering an energy pulse to the sputter gas to create a sputtering plasma, the sputtering plasma being formed by energy pulses having an average voltage between about 800 volts and about 2000 volts and an average current between about 50 amps and about 300 amps at a frequency which is less than 50 kHz and greater than 5 kHz; and
directing the sputtering plasma toward the dielectric-containing sputter target to form an ionized species comprising dielectric material sputtered from the dielectric-containing sputter target, the ionized species forming a dielectric-containing film on the substrate.

2. The method of claim 1, wherein the dielectric material comprises carbon.

3. The method of claim 2, wherein the energy pulse is delivered at a frequency between 30 and 40 kHz.

4. The method of claim 2, wherein the energy pulse is between 5 and 10 microseconds.

5. The method of claim 1, wherein the substrate is maintained at a pressure between about 2 mTorr and about 20 mTorr.

6. The method of claim 1, wherein the sputter target is a graphitic target.

7. The method of claim 1, wherein a width of the energy pulse is less than 100 microseconds and greater than 5 microseconds.

8. The method of claim 1, wherein the sputter gas comprises a gas which is inert to at least one of the substrate or the sputter target.

9. The method of claim 8, wherein the sputter gas comprises argon.

10. A generator for providing energy pulses for forming a dielectric film layer using a physical vapor deposition process, comprising:
a rectifier circuit to provide an energy charge;
an inverting circuit to invert the energy charge; and
a pulsing circuit to convert the inverted energy charge to energy pulses;
wherein the generator is configured to:
provide energy pulses to a sputter gas proximate a substrate positioned in a processing region of a process chamber, the process chamber having a dielectric-containing sputter target to create a sputtering plasma, the energy pulses having an average voltage between about 800 volts and about 2000 volts and an average current between about 50 amps and about 300 amps at a frequency which is less than 50 kHz and greater than 5 kHz.

11. The generator of claim 10, wherein the energy charge provided by the rectifier circuit comprises DC power.

12. The generator of claim 10, wherein the sputtering plasma is accelerated toward the dielectric-containing sputter target to form an ionized species comprising dielectric material sputtered from the dielectric-containing sputter target, the ionized species forming a dielectric-containing film on the substrate.

13. The generator of claim 10, wherein the generator generates energy pulses having widths less than 100 microseconds and greater than 5 microseconds.

14. A method of forming a carbon film layer using a physical vapor deposition process, comprising:
delivering a sputter gas to a substrate positioned in a processing region of a process chamber, the process chamber having a carbon-containing sputter target;
delivering an energy pulse to the sputter gas to create a sputtering plasma, the sputtering plasma being formed by energy pulses having an average voltage between about 800 volts and about 2000 volts and an average current between about 50 amps and about 300 amps at a frequency which is less than 50 kHz and greater than 5 kHz; and
forming an ionized species comprising a carbon material sputtered from the carbon-containing sputter target, wherein the ionized species forms a carbon-containing layer on the substrate.

15. The method of claim 14, wherein the substrate is maintained at a pressure between about 2 mTorr and about 20 mTorr.

16. The method of claim 14, wherein the sputter target is a graphitic target.

17. The method of claim 14, wherein a width of the energy pulse is less than 100 microseconds and greater than 5 microseconds.

18. The method of claim 14, wherein the sputter gas comprises a gas which is inert to at least one of the substrate or the sputter target.

19. The method of claim 18, wherein the sputter gas comprises argon.

20. The method of claim 14, wherein the energy pulse is delivered at a frequency between 30 and 40 kHz.
